(19) United States
(12) Patent Application Publication
(10) Pub. No.: US 2006/0163720 A1
(43) Pub. Date: Jul. 27, 2006

(54) Semiconductor device

(75) Inventor: Shinya Hirata, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/327,326

(22) Filed: Jan. 9, 2006

(30) Foreign Application Priority Data
Jan. 25, 2005 (JP) 2005-017483

(51) Int. Cl. H01L 23/12

(52) U.S. Cl. 257/704

(57) ABSTRACT

A semiconductor device is provided with a sealing ring 106 made of a metal which surrounds an integrated circuit part 102 and which is formed on a substrate 104 along an outer perimeter of the rectangular device. At least one corner part 108 of the sealing ring is formed to have a larger width than other parts of the sealing ring 106, so as to increase the rigidity and the strength of the corner part of the sealing ring 106. Thus, the strength of the corner part of the sealing ring is improved. Also, even if the corner part of the sealing ring is lost, the penetration of moisture into the integrated circuit side is inhibited.

This application is based on Japanese Patent application NO. 2005-017483, the content of which is incorporated hereinto by reference.

### BACKGROUND

1. Technical Field

The present invention relates to a semiconductor device provided with a sealing ring which is formed on a substrate along an outer perimeter of the device.

2. Related Art

A semiconductor device has a substrate on which numerous circuit elements are formed, and is constructed by interconnecting the circuit elements so as to perform predetermined operations, functions, and the like. In recent years, semiconductor devices are highly integrated, and the circuit elements and the interconnects are reduced in scale, so that the pitch of the interconnects tends to be smaller. When the pitch of the interconnects becomes small, the interconnect resistance increases, thereby necessitating adoption of copper interconnect lines having a low resistivity and insulating interlayers having a low dielectric constant.

These copper interconnect lines are susceptible to corrosion and, once they are corroded, a phenomenon such as increase in the interconnect resistance occurs, whereby the long-term reliability of the circuit is considerably deteriorated. This corrosion is not generated in a step of manufacturing a semiconductor device, but is generated by penetration of moisture into the integrated circuit side through the insulating interlayer during the long-term use of the product. An insulating interlayer having a low dielectric constant has a comparatively high moisture absorptivity, so that the device is generally provided with a sealing ring made of a metal which is formed in a rectangular shape on the substrate along an outer perimeter of the device, so as to prevent penetration of moisture into the inside by means of this sealing ring.

Here, since a chip-shaped semiconductor device is formed to have a rectangular shape, a stress is concentrated on the corner parts (angled parts) of the device when an external force is applied to the device at the time of handling the device. Therefore, various techniques are proposed to reinforce the corner parts of the sealing ring so as to prevent loss of the corner parts of the device (See, for example, Japanese Laid-Open patent publication Nos. 2003-338504 and 2004-253773).

In a semiconductor device disclosed in Japanese Laid-Open patent publication No. 2003-338504, a wall part similar to the sealing ring is further formed in the inside of the corner parts of the sealing ring so as to be spaced apart from the sealing ring. In a semiconductor device disclosed in Japanese Laid-Open patent publication No. 2004-253773, inwardly protruding rectangular parts are continuously formed at the corner parts of the sealing ring. According to these techniques, the stress on the corner parts of the device will be dispersed because a plurality of metal walls are formed at the corner parts of the device.

However, according to the semiconductor devices disclosed in Japanese Laid-Open patent publication Nos. 2003-338504 and 2004-253773, though the corner parts of the semiconductor devices are reinforced, the sealing ring itself is formed to have an almost constant width. Namely, concerning the sealing ring, the corner parts liable to receive a load are still fragile as compared with other parts of the device. Once the corner parts of the sealing ring are lost, the insulating interlayer will be exposed, whereby moisture penetrates into the integrated circuit side through the insulating interlayer.

### SUMMARY OF THE INVENTION

According to the present invention, there is provided a semiconductor device including a sealing ring made of a metal which surrounds an integrated circuit part and which is formed on a substrate along an outer perimeter of the rectangular device, wherein at least one corner part of the sealing ring is formed to have a larger width than other parts of the sealing ring.

With this semiconductor device, the corner part formed to have a larger width in the sealing ring will have an outstandingly improved rigidity and strength. Owing to the improvement in the rigidity and strength, the deformation around the corner part of the sealing ring in the device is restrained when a load is applied to the substrate and the sealing ring at the time of handling the device, so that the rigidity and strength of the whole device will be improved.

Here, a plurality of semiconductor devices are formed on one sheet of a wafer. After integrated circuit parts, sealing rings, and the like are formed, so-called post-processing steps such as dicing of the wafer and packaging of each semiconductor device are carried out. In these post-processing steps, impact and the like are applied to the separated rectangular semiconductor device, so that the end parts of the semiconductor device, particularly the corner parts, are liable to be deformed.

In this manner, a load will be applied to the corner parts of the sealing ring at the time of handling the device in the post-processing steps. Since the corner parts of the sealing ring have an improved rigidity and strength as described above, the loss of the corner parts of the sealing ring is prevented with certainty.

Also, the corner part is formed to have a comparatively large width. Therefore, even if an excessive load is applied to the device and the corner part of the sealing ring is lost together with the substrate, only the outer part of the corner part as viewed in the width direction is lost, so that the inner part of the corner part as viewed in the width direction will not be lost. Thus, even if the corner part is lost, air-tightness by means of the sealing ring is ensured, so that penetration of moisture into the integrated circuit side will be prevented.

According to a semiconductor device of the invention, the strength of a corner part of a sealing ring is improved. Also, even if the corner part of the sealing ring is lost, the penetration of moisture into the integrated circuit side is inhibited.

### BRIEF DESCRIPTION OF THE DRAWINGS

The above and other objects, advantages and features of the present invention will be more apparent from the following description taken in conjunction with the accompanying drawings, in which:

FIG. 1 is a model plan view of a semiconductor device showing one embodiment of the invention;

FIG. 2 is a cross-sectional view taken along the line A-A of FIG. 1;

FIG. 3 is a partial perspective outlook view of a sealing ring formed on a substrate, where a polyimide cover and an insulating interlayer are not drawn;

FIG. 4 is a partial plan view of a wafer before each semiconductor device is subjected to dicing;

FIG. 5 is a partial perspective outlook view of a sealing ring showing a state in which a corner part is lost, where a polyimide cover and insulating interlayers are not drawn;

FIG. 6 is a partial plan view of a sealing ring showing a modified example;

FIG. 7 is a partial plan view of a sealing ring showing a modified example;

FIG. 8 is a partial plan view of a sealing ring showing a modified example; and

FIG. 9 is a partial plan view of a sealing ring showing a modified example.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereafter, preferable embodiments of a semiconductor device according to the invention will be described with reference to the attached drawings. In the following embodiments, an example will be described in which a corner part formed to have a larger width in a sealing ring is formed to have a triangular shape in a plan view. Here, in the description of the drawings, the same elements will be denoted with the same symbols, and a duplicated description thereof will not be shown.

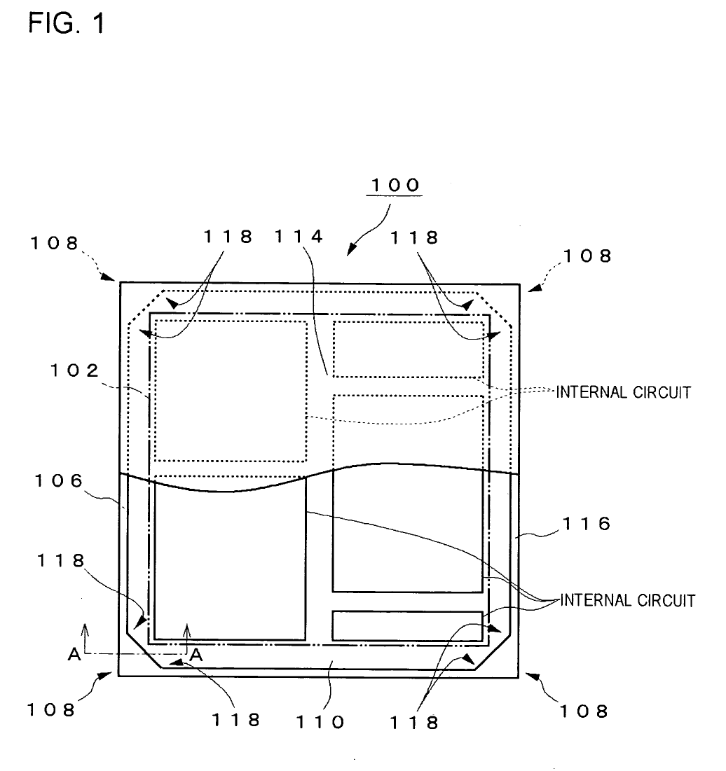

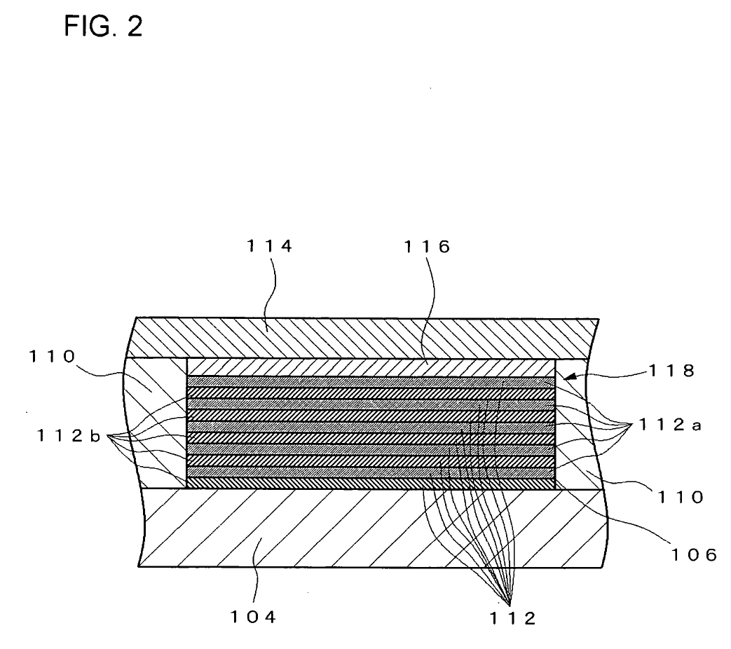

FIG. 1 is a model plan view of a semiconductor device showing one embodiment of the invention. FIG. 2 is a cross-sectional view taken along the line A-A of FIG. 1.

Referring to FIG. 1, this semiconductor device 100 includes a sealing ring 106 made of a metal which surrounds an integrated circuit part 102 and which is formed on a substrate 104 along an outer perimeter of the rectangular device, characterized in that at least one corner part 108 of the sealing ring 106 is formed to have a larger width than other parts of the sealing ring 106.

This semiconductor device 100 is called a “semiconductor chip”, and is formed to have a rectangular shape in a plan view. Here, the “rectangular shape” as referred to herein represents a right-angled quadrilateral. Referring to FIG. 2, the semiconductor device 100 includes a substrate 104 made of silicon, a plurality of insulating interlayers 110 disposed on this substrate 104, and electroconductive layers 112 buried in the insulating interlayers 110. In this embodiment, a sum of 10 electroconductive layers 112 are formed. The lowermost electroconductive layer 112 forms a contact plug in an integrated circuit part 102, and is constituted of tungsten. The other electroconductive layers 112 are constituted of copper, in which interconnect layers 112a and vi a plug layers 112b are alternately stacked. Also, a pad made of aluminum is disposed on the upper side of the uppermost insulating interlayer 110. A polyimide cover 114 which covers the upper surface of the device is disposed on the upper side of the pad.

The electroconductive layers 112 which establish electrical connection among various elements are stretched around in the integrated circuit part 102, and the gaps between the interconnects are filled with the insulating interlayers 110 made of a low dielectric constant film. The low dielectric constant film may be, for example, a SiOC film, a hydrogenated polysiloxane film, a methylpolysiloxane film, a hydrogenated methylpolysiloxane film, a film obtained by making these films porous, or the like. The low dielectric constant film may be an organic polymer as well. Referring to FIG. 1, the sealing ring 106 having a rectangular shape is formed on the outside of the integrated circuit part 102.

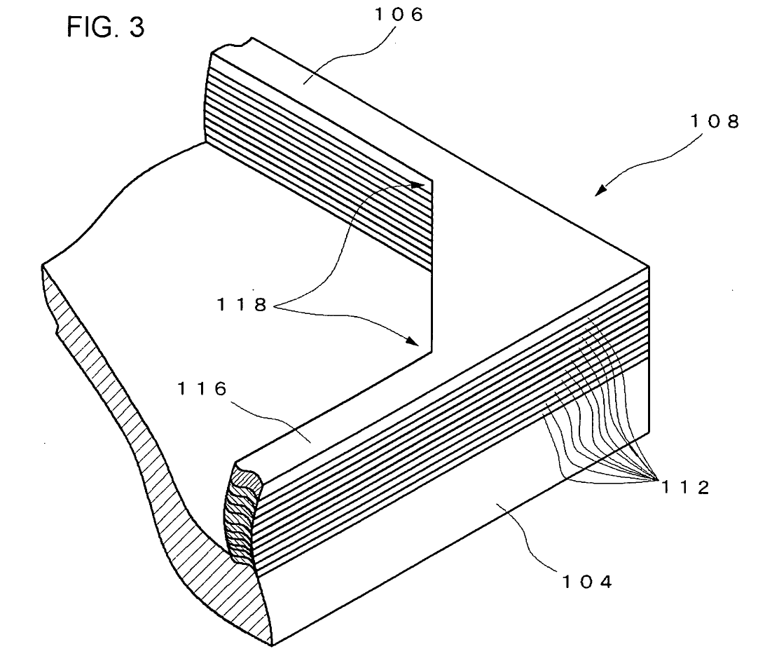

FIG. 3 is a partial perspective outlook view of a sealing ring formed on a substrate, where a polyimide cover and an insulating interlayer are not drawn.

Referring to FIG. 2, the sealing ring 106 has electroconductive layers 112 which are continuously formed in an up-and-down direction, and exhibits a wall shape which extends through the insulating interlayers 110 in the up-and-down direction. Namely, the sealing ring 106 is constituted by stacking a plurality of metal layers corresponding to the interconnect layers 112a and the via plug layers 112b in the integrated circuit part 102. The electroconductive layers 112 of the sealing ring 106 are formed independently from those of the integrated circuit part 102, and are not electrically connected to the integrated circuit part 102 (See FIG. 1). In this embodiment, the semiconductor device 100 is manufactured by the damascene process, where the electroconductive layers 112 of the integrated circuit part 102 and the sealing ring 106 are manufactured simultaneously through one and the same step.

Referring to FIG. 3, the wall-shaped part of the sealing ring 106 is formed to have the same width dimension along the up-and-down direction. In this embodiment, the sealing ring 106 has an aluminum layer 116 which is formed continuously to the electroconductive layers 112 and corresponds to the aluminum pad in the integrated circuit part 102.

Each corner part 108 of the sealing ring 106 is formed to have a larger width than other parts of the sealing ring 106. In this embodiment, each corner part 108 is formed in a right-angled isosceles triangle shape with its hypotenuse positioned in the inside as viewed in a plan view. Referring to FIG. 1, the outer perimeter of the sealing ring 106 exhibits a right-angled quadrilateral shape in a plan view, and the inner perimeter of the sealing ring 106 has a shape which protrudes to the inside at the corner parts 108. Namely, the inner perimeter surface of the corner parts 108 which are formed to have a larger width has two corner intervals (angled intervals) 118 which are formed to have an angle larger than a right angle in a plan view, and the other intervals are formed to have a straight line shape. In this embodiment, each corner interval 118 is formed to have an angle of approximately 135° in a plan view.

Also, referring to FIG. 2, at each corner part 108 formed to have a larger width, in the same manner as in the other parts formed to have a wall shape, each of the metal layers corresponding to the interconnect layers 112a and the via plug layers 112b is formed to have the same width dimension in the up-and-down direction. Here, at each corner part 108, an aluminum layer 116 is formed to have the same width dimension continuously to each electroconductive layer 112.

According to the semiconductor device 100 constructed as shown above, the air-tightness of the integrated circuit part 102 on the substrate 104 is ensured at the top by means of the polyimide cover 114 and at the sides by means of the sealing ring 106.

With the semiconductor device 100 of this embodiment, the corner part 108 formed to have a larger width in the sealing ring 106 will have an outstandingly improved rigidity and strength. Owing to the improvement in the rigidity and strength of the corner part 108, the deformation around the corner part 108 of the sealing ring 106 in the device is restrained when a load is applied to the substrate 104 and the sealing ring 106 at the time of handling the device, so that the rigidity and strength of the whole device will be improved.

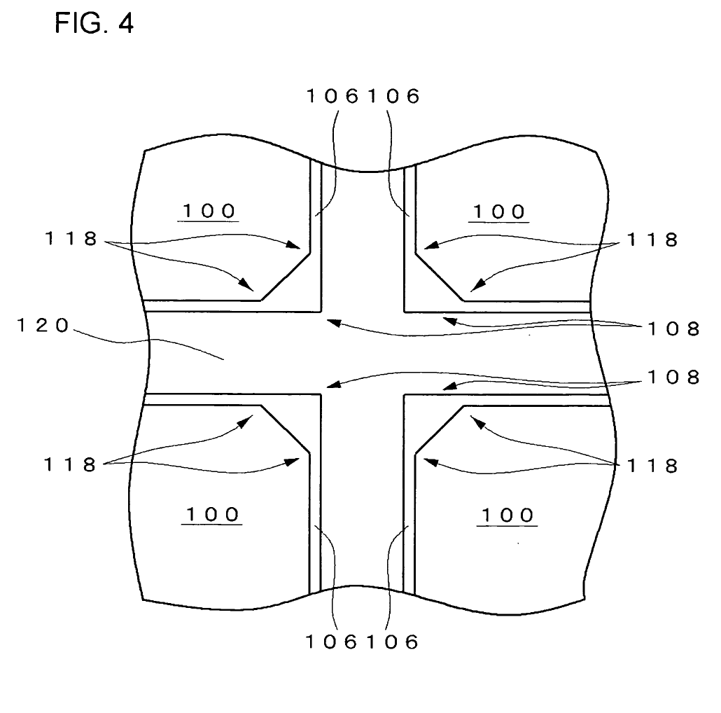

Here, referring to FIG. 4, a plurality of semiconductor devices 100 are manufactured continuously on one sheet of a wafer, where the integrated circuit parts 102, the sealing rings 106, and others are formed. FIG. 4 is a partial plan view of a wafer before each semiconductor device is subjected to dicing. Thereafter, the wafer is subjected to dicing along a scribed line 120 so that each semiconductor device 100 will be separated. After the dicing of the wafer, each semiconductor device 100 is transported by being mounted on a tray, and proceeds to steps such as packaging. In these so-called post-processing steps, impact and the like are applied to the separated rectangular semiconductor device 100, so that the end parts of the semiconductor device 100, particularly the corner parts, are liable to be deformed.

In this manner, a load will be applied to the corner parts 108 of the sealing ring 106 at the time of handling the device in the post-processing steps. Since the corner parts 108 of the sealing ring 106 have an improved rigidity and strength as described above, the loss of the corner parts 108 of the sealing ring 106 is prevented with certainty.

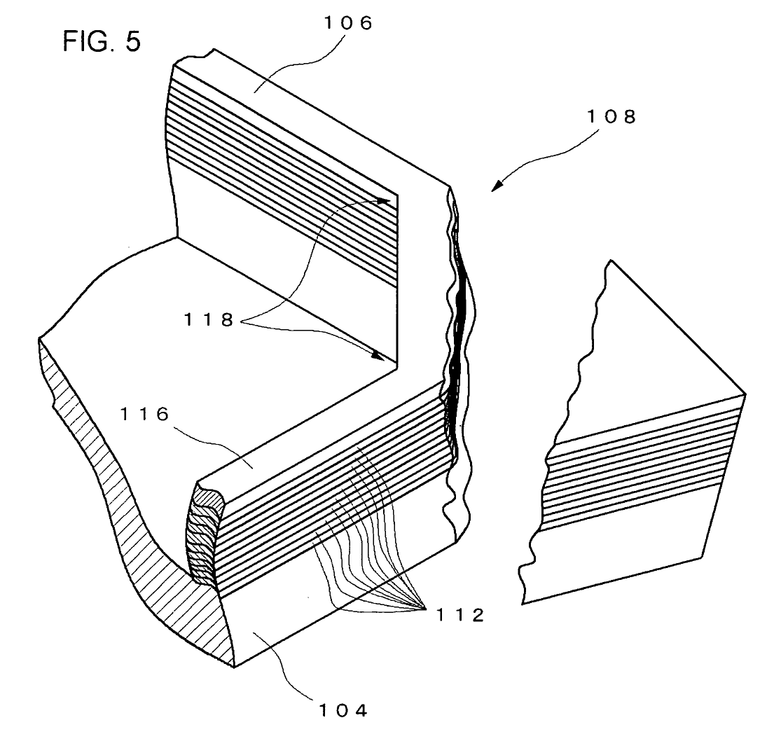

Also, the corner part 108 is formed to have a comparatively large width. Therefore, even if an excessive load is applied to the device and the corner part 108 of the sealing ring 106 is lost together with the substrate 104, only the outer part of the corner part 108 (as viewed in the width direction) is lost as shown in FIG. 5, so that the inner part of the corner part 108 will not be lost. FIG. 5 is a partial perspective outlook view of the sealing ring 106 showing a state in which the corner part 108 of the sealing ring 106 is lost, where the polyimide cover and the insulating interlayers are not drawn. Thus, even if the corner part 108 is lost, air-tightness by means of the sealing ring 106 is ensured, so that penetration of moisture into the integrated circuit 102 side will be prevented. At this time, the wider the corner part 108 is, the larger the margin at the time of the loss will be.

Also, according to the semiconductor device 100 of this embodiment, since the corner parts 108 are made of a metal continuously over the whole surface in the up-and-down direction on the substrate 104, the strength of the corner parts 108 can be outstandingly improved. In particular, in this embodiment, since the insulating interlayers 110 are made of a low dielectric constant film having a comparatively low mechanical strength, the fragility at the part of the insulating interlayers 110 can be efficiently compensated for.

Here, though the electroconductive layers 112 are formed over the whole surface of the corner part 108, this is a rough pattern which does not require a high accuracy as compared with the integrated circuit part 102. Therefore, even if the electroconductive layers 112 are polished a little too much by CMP at the corner parts 108, no particular inconvenience occurs.

Also, according to the semiconductor device 100 of this embodiment, since the corner part 108 is formed to have a triangular shape with its hypotenuse facing inward, the space on each integrated circuit 102 side can be ensured to be comparatively large.

Here, in the above-described embodiment, a semiconductor device has been shown in which all the corner parts 108 are formed to have a larger width. However, as long as at least one corner part 108 is formed to have a larger width, the rigidity and the strength around the corner part 108 can be improved. Namely, one can arbitrarily decide whether the corner part 108 will be made to have a larger width or not in accordance with the layout of the integrated circuit part 102, the way a load is applied to the corner part 108 in the post-processing steps, and the like. The width dimension of each corner part 108 is also arbitrary.

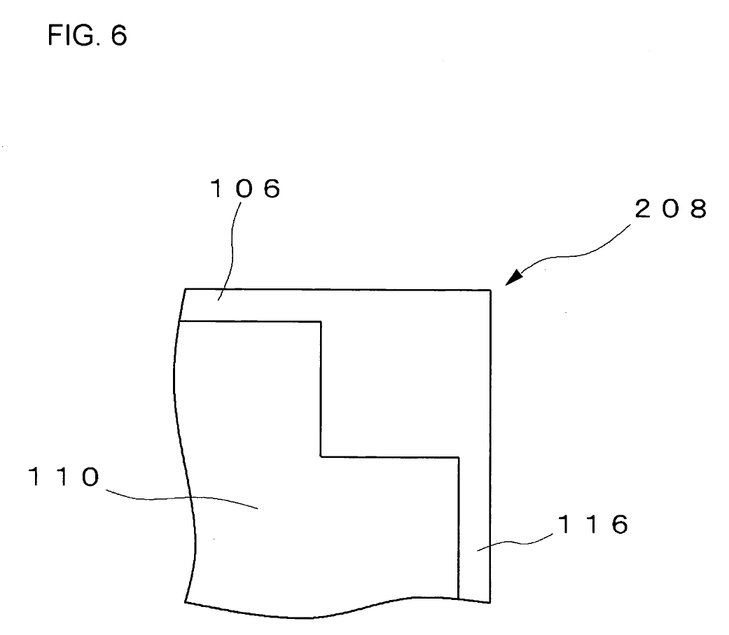

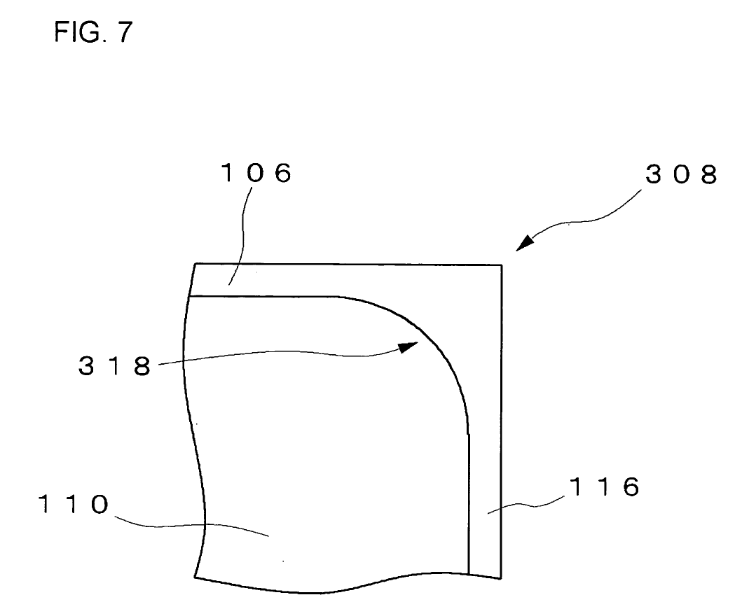

In the above-described embodiment, a semiconductor device has been shown in which the corner part 108 is formed to have a triangular shape in a plan view. Alternatively, a corner part 208 may be formed, for example, to have a quadrangular shape as shown in FIG. 6, or an inner circumferential surface of a corner part 308 may be formed, for example, to have a circular arc shape as shown in FIG. 7.

When the corner part 208 is formed to have a generally quadrangular shape, the area of the corner part 208 will be comparatively large, so that the margin at the time of the loss of the corner part 208 can be ensured to be large, thereby providing an advantage for holding the air-tightness of the integrated circuit part 102.

Also, when the inner circumferential surface of the corner part 308 is formed to have a circular arc-shaped interval 318 as shown in FIG. 7, an angle (a corner) is not formed on the inner circumferential surface, so that the cross-sectional coefficient changes smoothly towards the circumferential direction, thereby being effective for avoiding stress concentration. Here, corresponding to the layout or the like of the integrated circuit-part 102, corner intervals 118 such as in the above-described embodiment and circular arc-shaped intervals 318 may be combined to form the inner circumferential surface of a corner part.

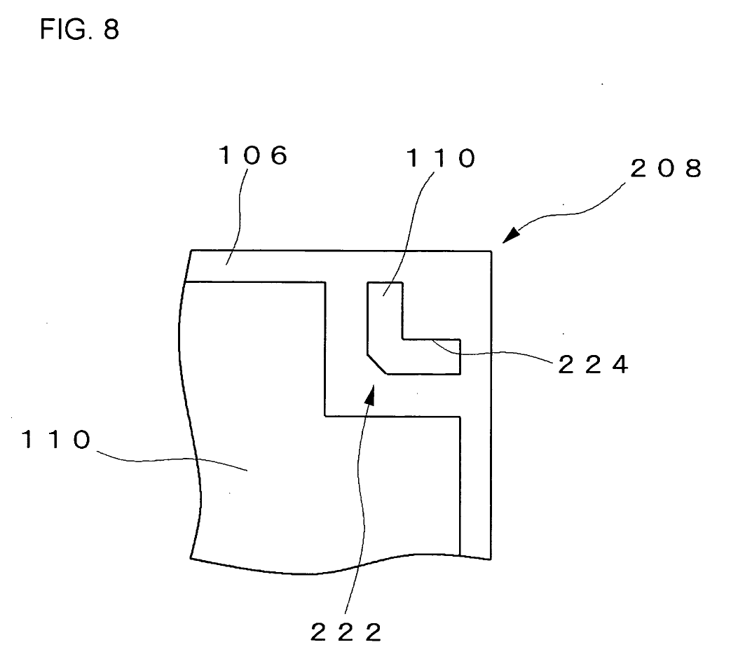

Also, as shown for example in FIG. 8, a recognition pattern 222 may be formed in the corner part 208 which is formed to have a larger width. This allows that the corner part 208 has both a function of preventing moisture penetration into the integrated circuit part 102 and a function of recognizing the corner part for other devices, thereby being extremely advantageous in practical use. FIG. 8 shows a case in which, as a recognition pattern 222, the electroconductive layer 112 is not formed on the central side of the corner part 208 but a cut-out region 224 filled with the insulating interlayer 110 is formed. This corner part 208 is formed to have a quadrangular shape, where a generally L-shaped cut-out region 224 is formed to be parallel to the inner perimeter of the corner part 208.

This recognition pattern 222 is for grasping the posture of the semiconductor device 100 in other devices at the time of handling the semiconductor device 100 in the post-processing steps. For example, in dicing the wafer, a dicing apparatus recognizes the position and the posture of each semiconductor device 100 with the use of the recognition pattern 222 by an optical technique, so as to cut out the wafer.

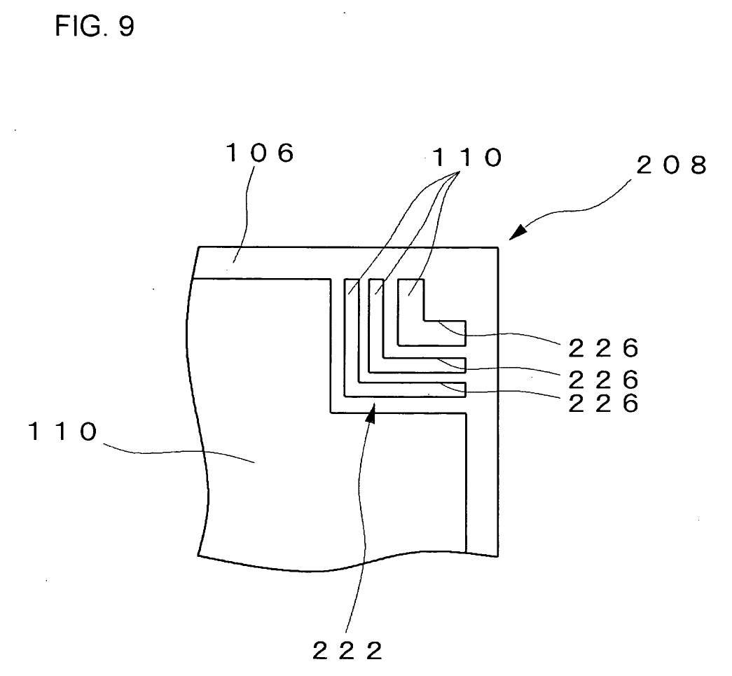

Here, for forming this recognition pattern 222, it is sufficient to form a region where at least one electroconductive layer 112 from the upper side is not formed instead of absence of formation of all the electroconductive layers 112. Namely, it is sufficient that the recognition pattern 222 has a hole-shaped cut-out region which is formed in an upper part of the corner part 208. Also, the recognition pattern 222 may have an arbitrary shape, and a plurality of cut-out regions 224 where the electroconductive layers 112 is not formed may be present as shown, for example, in FIG. 9. FIG. 9 shows a case in which three generally L-shaped cut-out regions 226 are formed in a corner part 208 formed to have a quadrangular shape.

In the above-described embodiment, the electroconductive layers 112 of the interconnects are made of copper; however, the electroconductive layers 112 may be made of other metals. In addition, it goes without saying that specific fine structures and the like can be suitably modified and changed.

It is apparent that the present invention is not limited to the above embodiment, which may be modified and changed without departing from the scope and spirit of the invention.

What is claimed is:

1. A semiconductor device comprising a sealing ring made of a metal which surrounds an integrated circuit part and which is formed on a substrate along an outer perimeter of the rectangular device,
wherein at least one corner part of said sealing ring is formed to have a larger width than other parts of the sealing ring.

2. The semiconductor device according to claim 1,
wherein said sealing ring is formed by laminating a plurality of metal layers corresponding to interconnect layers and via plug layers in said integrated circuit part, and
the corner part formed to have a larger width in said sealing ring is formed in such a manner that the metal layers respectively corresponding to said interconnect layers and said via plug layers are formed to have an identical width dimension along an up-and-down direction.

3. The semiconductor device according to claim 2,
wherein a recognition pattern for recognition of the corner part is formed in the corner part which is formed to have a larger width in said sealing ring.

4. The semiconductor device according to claim 3,
wherein said recognition pattern has a hole-shaped cut-out region which is formed in an upper part of said corner part.

5. The semiconductor device according to claim 4,
wherein said corner part formed to have a larger width is formed to have a quadrangular shape in a plan view.

6. The semiconductor device according to claim 4,
wherein said corner part formed to have a larger width is formed to have a triangular shape in a plan view.

7. The semiconductor device according to claim 4,
wherein an inner circumferential surface of said corner part formed to have a larger width has a circular arc-shaped interval in a plan view.

8. The semiconductor device according to claim 5,
wherein an inner circumferential surface of said corner part formed to have a larger width has a corner interval formed to have a larger angle than a right angle in a plan view.

9. The semiconductor device according to claim 6,
wherein an inner circumferential surface of said corner part formed to have a larger width has a corner interval formed to have a larger angle than a right angle in a plan view.

10. The semiconductor device according to claim 1,
wherein a recognition pattern for recognition of the corner part is formed in the corner part which is formed to have a larger width in said sealing ring.

11. The semiconductor device according to claim 10,
wherein said recognition pattern has a hole-shaped cut-out region which is formed in an upper part of said corner part.

12. The semiconductor device according to claim 11,
wherein said corner part formed to have a larger width is formed to have a quadrangular shape in a plan view.

13. The semiconductor device according to claim 11,
wherein said corner part formed to have a larger width is formed to have a triangular shape in a plan view.

14. The semiconductor device according to claim 11
wherein an inner circumferential surface of said corner part formed to have a larger width has a circular arc-shaped interval in a plan view.

15. The semiconductor device according to claim 12,
wherein an inner circumferential surface of said corner part formed to have a larger width has a corner interval formed to have a larger angle than a right angle in a plan view.

16. The semiconductor device according to claim 13,
wherein an inner circumferential surface of said corner part formed to have a larger width has a corner interval formed to have a larger angle than a right angle in a plan view.

17. The semiconductor device according to claim 1,
wherein said corner part formed to have a larger width is formed to have a quadrangular shape in a plan view, and
an inner circumferential surface of said corner part formed to have a larger width has a corner interval formed to have a larger angle than a right angle in a plan view.

18. The semiconductor device according to claim 1, wherein said corner part formed to have a larger width is formed to have a triangular shape in a plan view, and
an inner circumferential surface of said corner part formed to have a larger width has a corner interval formed to have a larger angle than a right angle in a plan view.

19. The semiconductor device according to claim 1,
wherein an inner circumferential surface of said corner part formed to have a larger width has a circular arc-shaped interval in a plan view.
